(19) United States
(12) Patent Application Publication
(10) Pub. No.: US 2015/0037024 A1
(43) Pub. Date: Feb. 5, 2015

(54) MEMS IRIS DIAPHRAGM-BASED FOR AN OPTICAL SYSTEM AND METHOD FOR ADJUSTING A SIZE OF AN APERTURE THEREOF

(71) Applicant: NATIONAL UNIVERSITY OF SINGAPORE, Singapore (SG)

(72) Inventors: Guangya Zhou, Singapore (SG); Hongbin Yu, Singapore (SG); Fook Siong Chau, Singapore (SG)

(21) Appl. No.: 14/480,209

(22) PCT Filed: Mar. 6, 2013
(86) PCT No.: PCT/SG2013/000093

§ 371 Date: Sep. 8, 2014

Related U.S. Application Data
(60) Provisional application No. 61/607,859, filed on Mar. 7, 2012.

(51) Int. Cl. G03B 9/06; B81B 7/02; B81B 5/00

(52) U.S. Cl. CPC G03B 9/06; B81B 5/00; B81B 7/02
USPC 396/510

(57) ABSTRACT

A MEMS iris diaphragm (400) for an optical system is disclosed. The MEMS iris diaphragm (400) comprises at least two layers of diaphragm structures with each layer having suspended blade members (404a, 404b, 404c, 404d, 406a, 406b, 406c, 406d) angularly spaced from each other, the at least two layers of blade members (404a, 404b, 404c, 404d, 406a, 406b, 406c, 406d) arranged to overlap and cooperate with each other to define an aperture (408) to allow light to pass through, and a rotary actuating device (401) arranged to rotate at least some of the blade members (404a, 404b, 404c, 404d, 406a, 406b, 406c, 406d) of the at least two layers about their respective axis in a non-contact manner to vary the aperture's size. A method of adjusting a size of an aperture of a MEMS iris diaphragm (400) for an optical system is also disclosed.

### FIELD & BACKGROUND

The present invention relates to a MEMS iris diaphragm for an optical system and method for adjusting a size of an aperture thereof.

Iris diaphragm is a basic component used in optical systems. Particularly, the iris diaphragm includes an aperture whose size may be adjusted to allow luminous flux, field of view and depth of field to be controlled, as well as enable light scattering to be prevented, which consequently leads to improvement of image quality. Tunability of the size of the aperture is thus an important characteristic for any iris diaphragm. In recent years, ubiquitous use of smartphones and tablet PCs has triggered significant research interest in miniaturised cameras. Hence, Micro-Electro-Mechanical Systems (MEMS) based variable apertures that are adaptable for use in miniaturised cameras, are accordingly receiving more attention and interest.

In macroscopic optical systems, apertures of iris diaphragms are formed of multiple blades in consecutive overlapping arrangement to define a polygonal opening that can enlarge or shrink, through rotation of the blades thereby allowing them to slide over each other (i.e. see FIG. 1). However, it is difficult to achieve miniaturisation of such optical systems.

One early work reported in the area of miniature apertures involves a design using multiple in-plane sliding blades as shown in FIG. 2, in which the sliding blades are driven by micro-actuators to move in-plane translationally to enlarge an aperture 202 (see the transition from FIGS. 2a to 2b). While simple in structure, this design is however only able to provide a limited aperture diameter adjustment range of less than 100 μm, due to the stroke limitations of the micro-actuators (typically larger than 10 μm in size). Hence, although the design may be useful for Fiber Variable Optical Attenuators (VOAs) applications, since the diameters of the fiber mode fields are typically limited to only a few 10 μm, the design is however not suited for application to most commercial miniature cameras, which have lens diameters of generally between 2 mm to 3 mm.

To overcome the limited aperture adjustment range problem, and to realise an adjustable aperture device suitable for miniature cameras, another design attempts to develop a variable optical aperture based on optofluidic-platform. The variable aperture is fabricated using Polydimethylsiloxane (PDMS) soft lithography and tuned when the light absorption dye in a chamber is forced aside by a deformable PDMS membrane through air pumping, as depicted in FIG. 3. This design was shown to enable an aperture diameter tuning range from 0 mm to 6.35 mm to be achieved. Several other optofluidic-platform designs utilising dielectric forces, piezoelectric actuation, and capillary forces were also subsequently developed. However, optofluidic-platform based adjustable aperture designs nevertheless have their drawbacks, such as device packaging complications (e.g. liquid leakage and evaporation), vibration and thermal stability issues, and related complexities to drive the type of fluid used.

One object of the present invention is therefore to address at least one of the problems of the prior art and/or to provide a choice that is useful in the art.

### SUMMARY

According to a 1^{st} aspect of the invention, there is provided a MEMS iris diaphragm for an optical system. The MEMS iris diaphragm comprises at least two layers of diaphragm structures with each layer having suspended blade members angularly spaced from each other, the at least two layers of blade members arranged to overlap and cooperate with each other to define an aperture to allow light to pass through, and a rotary actuating device arranged to rotate at least some of the blade members of the at least two layers about their respective axis in a non-contact manner to vary the aperture's size.

Advantages of the proposed MEMS iris diaphragm include having an increased device lifetime as the rotary blades of the same layer or different layers do not slide between or contact one another during device operation, which consequently eliminates friction generation that may cause unwanted wear and tear of the rotary blades. Further, the MEMS iris diaphragm is non-fluid based, which reduces complexities in device packaging and system integration, not to also mention that there is also greater ease in actuation of the aperture. In addition, the MEMS iris diaphragm has a large millimetre-scale aperture diameter adjustment range, and has a relatively fast response time of about a few milliseconds.

Preferably, each blade member may be suspended at one end to a common substrate. Alternatively, the blade members of each layer may be suspended at one end to different substrates. Yet further, the rotary actuating device may include a plurality of rotary actuators, each actuator arranged to rotate one or more blade members.

Preferably, the rotary actuating device may include a single rotary actuator, which drives all blade members to rotate. Further preferably, each layer of the diaphragm structure may have at least two blade members. In addition, the aperture may have a polygonal shape. More specifically, the polygonal shape may be octagonal or hexagonal.

Yet preferably, each rotary actuator may be an electrostatic comb-drive actuator. Further also, the rotary actuating device and the blade members may be arranged on a common substrate. Optionally, the rotary actuating device and the blade members may preferably be arranged on different respective substrates. It is to be appreciated that the aperture's size may preferably be variable between a maximum diameter of 5 mm and a minimum diameter of 0 mm.

Further preferably, each blade member may be configured with substantially straight edges. Alternatively, each blade member may also be configured with curved edges.

Preferably, each blade member may include an extension arm for attaching to the rotary actuating device. Alternatively, each blade member may be directly attached to the rotary actuating device.

In addition, the at least two layers of diaphragm structures may preferably include first and second layers, in which the first layer has an odd number of blade members, and the second layer has an even number of blade members. It should be appreciated that the first layer might be a “top” or “bottom” layer relative to the second layer. Alternatively, the first and second layers may have odd number of blade members or may have even number of blade members.

It is envisaged that at least some of the blade members are rotated to adjust the aperture size or the rotary actuating device is arranged to rotate each of the blade members of the at least two layers.

According to a second aspect of the invention, there is provided an optical system comprising the MEMS iris diaphragm of the 1^{st} aspect of the invention.

According to a third aspect of the invention, there is provided a method of adjusting a size of an aperture of a MEMS iris diaphragm for an optical system, in which the MEMS iris diaphragm includes at least two layers of diaphragm structures with each layer having suspended blade members angularly spaced from each other, the at least two layers of blade members arranged to overlap and cooperate with each other to define an aperture to allow light to pass through. The method comprises rotating at least some of the blade members of the at least two layers about their respective axis in a non-contact manner, by a rotary actuating device, to vary the aperture's size.

It should be apparent that features relating to one aspect of the invention may also be applicable to the other aspects of the invention.

These and other aspects of the invention will be apparent from and elucidated with reference to the embodiments described hereinafter.

### BRIEF DESCRIPTION OF THE DRAWINGS

Embodiments of the invention are disclosed hereinafter with reference to the accompanying drawings, in which:

FIG. 1 shows a conventional iris diaphragm, according to prior art;

FIGS. 2a and 2b depict an operation of a conventional miniature aperture having a single layer of in-plane translational sliding blades, according to the prior art;

FIG. 3 is a optofluidic-platform based variable optical aperture, according to the prior art;

FIGS. 4a and 4b are schematic diagrams of plan views showing a MEMS iris diaphragm, according to a first embodiment of the invention;

FIG. 5a is a schematic diagram depicting a plan view of a second layer of rotary blades of the MEMS iris diaphragm of FIG. 4;

FIG. 5b depicts how an aperture size of the aperture of the MEMS iris diaphragm of FIG. 4 is defined;

FIG. 5c depicts how a blade rotation angle of each rotary blade forming the MEMS iris diaphragm of FIG. 4 is defined;

FIG. 6a is a schematic diagram illustrating detailed operation of the MEMS iris diaphragm of FIG. 4;

FIG. 6b is a graph illustrating the relationship between the aperture adjustment ratio “dₘₐₓ/dₘᵢₙ” and design ratio “a/b”, investigated at different maximum blade rotation angle “αₘₐₓ”, with reference to FIG. 6a;

FIGS. 7a to 7c show an implementation of the MEMS iris diaphragm of FIG. 4, which is assembled using two MEMS chips;

FIG. 8 is a schematic diagram of a rotary blade and the associated MEMS rotary actuator;

FIG. 9 is an enlarged microscopic image of a section of a fabricated MEMS chip used to form the MEMS iris diaphragm of FIG. 4, and the inset shows a microscope image of the complete fabricated MEMS chip;

FIG. 10 is a graph illustrating performance results of a fabricated prototype device based on the design implementation of FIG. 7c; and

FIG. 11a is a schematic diagram of a MEMS iris diaphragm based on a single MEMS chip design, according to a second embodiment, and FIG. 11b is an isometric view of FIG. 11a.

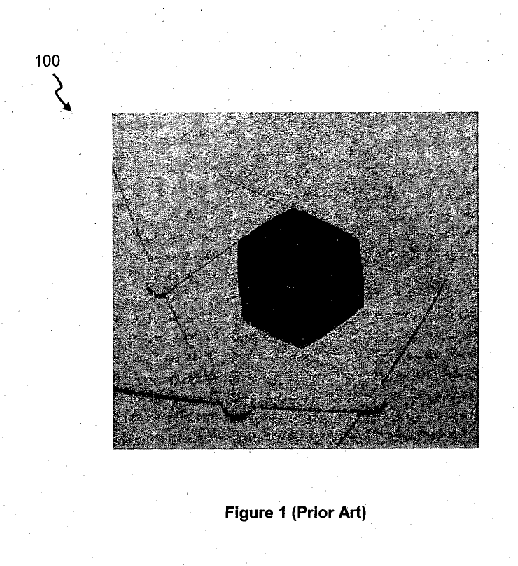

### DETAILED DESCRIPTION OF PREFERRED EMBODIMENTS

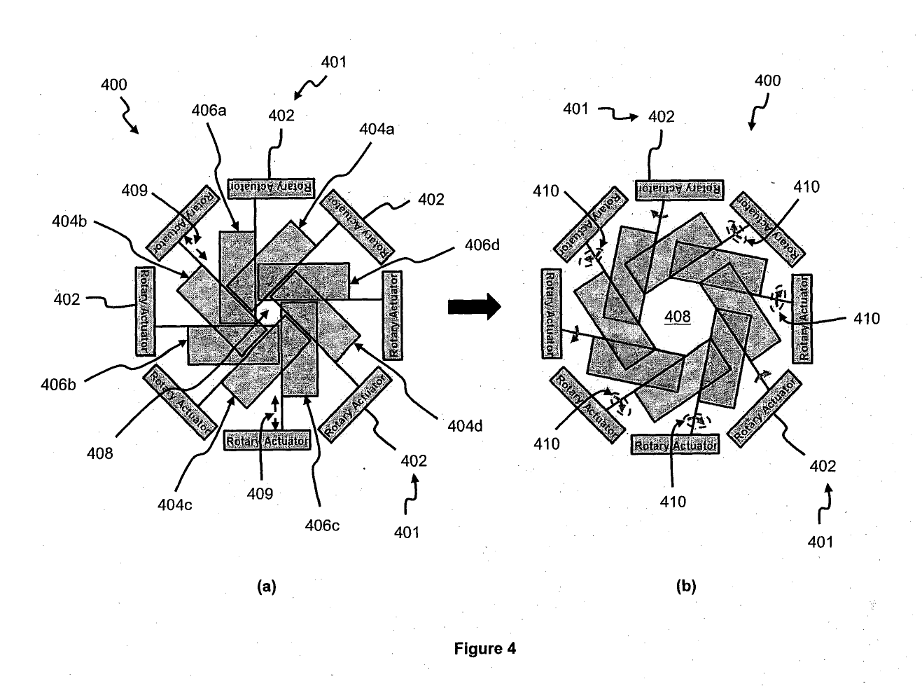

According to a first embodiment, FIG. 4a schematically shows a Micro-Electro-Mechanical Systems (MEMS) iris diaphragm 400, for an optical system, formed of two separate layers of diaphragm structures that comprise rotary blades, which are configured to be rotationally driven about their respective axis by corresponding rotary actuating devices 401, each of which includes associated MEMS rotary actuators 402. Each layer of diaphragm structures is formed on a respective substrate, as to be elaborated below. In this embodiment, the MEMS rotary actuators 402 are implemented using electrostatic comb-drive actuators. A top first layer comprises four rotary blades 404a, 404b, 404c, 404d which are in overlapping arrangement to a bottom second layer of four rotary blades 406a, 406b, 406c, 406d. Moreover, the rotary blades 404a, 404b, 404c, 404d, 406a, 406b, 406c, 406d of each layer are angularly spaced from one another. In the overlapping arrangement, all eight rotary blades 404a, 404b, 404c, 404d, 406a, 406b, 406c, 406d collectively cooperate to define an aperture 408 to allow light to pass through. In this embodiment, the aperture 408 is polygonal-shaped and more specifically, is in the form of an octagon.

Each rotary blade 404a, 404b, 404c, 404d, 406a, 406b, 406c, 406d is opaque in material composition, and movably attached to the associated MEMS rotary actuator 402 by way of an integrally formed extension arm 409 that extends from a lengthwise edge of the corresponding rotary blade 404a, 404b, 404c, 404d, 406a, 406b, 406c, 406d. More specifically, each rotary blade 404a, 404b, 404c, 404d, 406a, 406b, 406c, 406d is in a suspended arrangement relative to the underlying substrate through attachment of the extension arm 409 to the associated MEMS rotary actuator 402. To drive the rotary blades 404a, 404b, 404c, 404d, 406a, 406b, 406c, 406d, the corresponding MEMS rotary actuators 402 thus simply move the associated extension arms 409 as attached thereto.

As mentioned above, in the overlapping arrangement, all the rotary blades 404a, 404b, 404c, 404d, 406a, 406b, 406c, 406d cooperate to define the aperture 408. It will be appreciated that each rotary blade 404a, 404b, 404c, 404d, 406a, 406b, 406c, 406d is formed rectangular in shape (as an example), with straight edges. When each rotary blade 404a, 404b, 404c, 404d, 406a, 406b, 406c, 406d is driven by corresponding MEMS rotary actuators 402 to rotate in a clockwise manner (as indicated by the direction of arrows 410 shown in FIG. 4b), the aperture 408 enlarges as shown in FIG. 4b. Conversely, the aperture 408 shrinks if the rotary blades 404a, 404b, 404c, 404d, 406a, 406b, 406c, 406d are driven to rotate in a counter-clockwise manner (not shown) as will be understood. Further, it is highlighted that in the overlapping arrangement, a small gap (not shown) vertically separates the first layer of four rotary blades 404a, 404b, 404c, 404d from the second layer of four rotary blades 406a, 406b, 406c, 406d, and consequently, there are no contacting/sliding surfaces between the rotary blades 404a, 404b, 404c, 404d, 406a, 406b, 406c, 406d when being driven by the MEMS rotary actuators 402. It is to be appreciated that the small gap is configured to be as small as reasonably possible (based on current available manufacturing tolerances) in order to enable the rotary blades 404a, 404b, 404c, 404d, 406a, 406b, 406c, 406d of the first and second layers to move in a non-contact manner with respect to one another. This beneficially avoids generation of friction, and thus mitigates wear and tear during operation of the MEMS iris diaphragm 400.

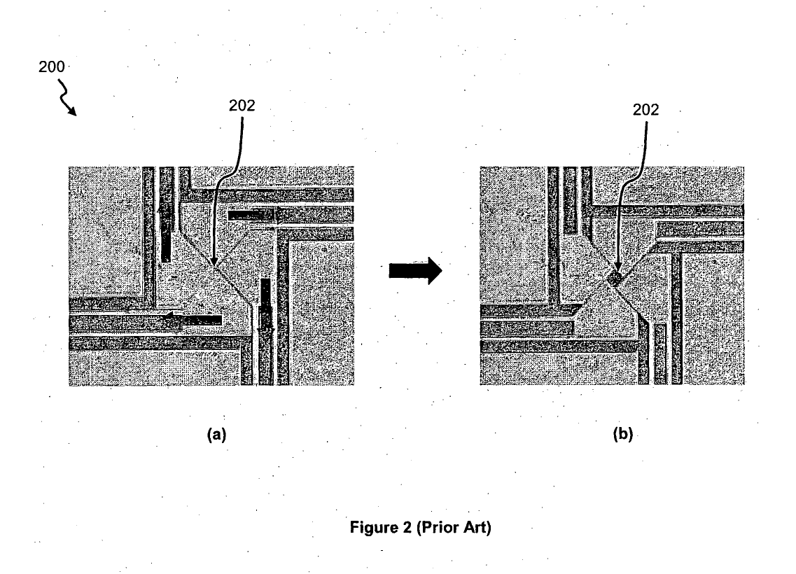

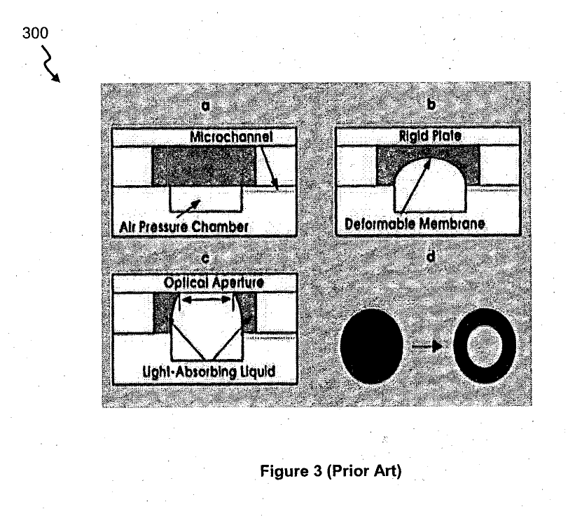

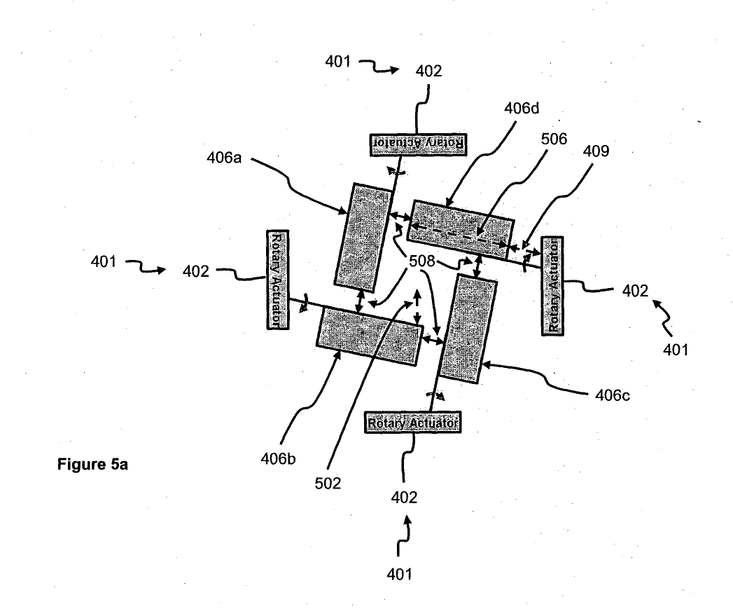

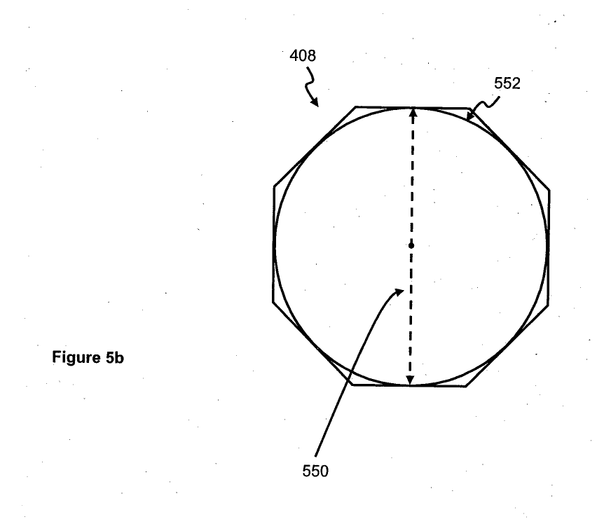

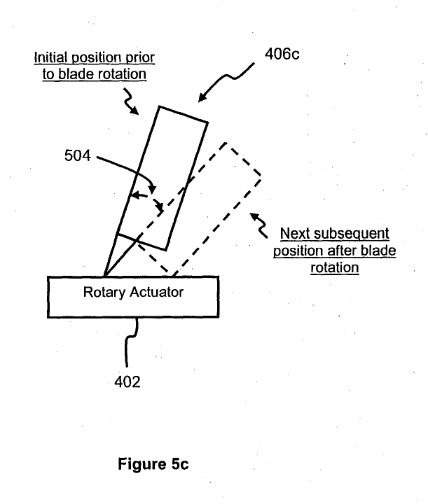

It is to be noted that the proposed MEMS iris diaphragm 400 is characterised with a few unique features. In this regard, with reference to FIG. 5a, the MEMS iris diaphragm 400 employs use of the MEMS rotary actuators 402, over translational actuators used in the prior art (i.e. refer to FIG. 2), which consequently greatly enhances the aperture size adjustment range 502 of the aperture 408. It will be seen from FIG. 5b that the aperture size is defined as the diameter 550 of an inscribed circle 552 of the aperture 408, which is polygonal-shaped as aforementioned (and specifically in this instance is an octagon). It will however be appreciated that this definition for the aperture size is applicable to apertures with straight edges, and apertures with instead curved edges will accordingly have different definitions, as will be understood by skilled persons. In addition, referring now to the translational-driven blades shown in FIG. 2, the aperture size adjustment range of the miniature aperture design of FIG. 2 is limited by the maximum strokes of the driving micro-actuators, which is typically of a few hundred of micrometres. This is thus in contrast to the rotary blades 406a, 406b, 406c, 406d in the second layer of the current embodiment shown in FIG. 5a, where the aperture size adjustment range 502 is instead determined by a blade rotation angle 504, in conjunction with the extension arm 409 and length 506 of each rotary blade 406a, 406b, 406c, 406d. Specifically, from the plan view of FIG. 5c, the blade rotation angle 504 is defined as a displacement angle that a rotary blade (i.e. a rotary blade 406c of the second layer is used as an example in FIG. 5c for illustration) forms when the rotary blade 406c moves from a initial position prior to rotation (as depicted by the rotary blade 406c drawn with solid lines in FIG. 5c) to a next subsequent position immediate to completion of the rotation (as depicted by the rotary blade 406c drawn with dotted lines in FIG. 5c). Importantly, it is to be appreciated that large rotation angles (of approximately a few tens of degrees) can be achieved using the proposed MEMS rotary actuators 402 design, enabling the MEMS iris diaphragm 400 to be configured with a large aperture size adjustment range 502 at a scale of a few millimetres. It will be understood that this discussion applies similarly for the rotary blades 404a, 404b, 404c, 404d of the first layer, but for sake of brevity will be not repeated.

Further, for the proposed MEMS iris diaphragm 400, at least two layers of the rotary blades 404a, 404b, 404c, 404d, 406a, 406b, 406c, 406d are necessary to successfully define the aperture 408. To see why this is so, FIG. 5a illustrates that when the rotary blades 406a, 406b, 406c, 406d in the second layer are rotated to move clockwise, the rotary blades 406a, 406b, 406c, 406d subsequently separate and, as a result the horizontal gaps 508 between neighbouring adjacent rotary blades 406a, 406b, 406c, 406d widen increasingly to a point of eventually allowing light to undesirably leak through the widened horizontal gaps 508, as will be apparent. Therefore, it will be apparent that if there is only one layer of rotary blades 406a, 406b, 406c, 406d, the leakage of light through the horizontal gaps 508 cannot easily be remedied. However, for the proposed MEMS iris diaphragm 400 (i.e. refer to FIG. 4), the first and second layers of rotary blades 404a, 404b, 404c, 404d, 406a, 406b, 406c, 406d are arranged to overlap one another to define the aperture 408, which is maintained in that shape across the entire aperture size adjustment range 502. Specifically, it will indeed be apparent that the horizontal gaps 508 between adjacent rotary blades 404a, 404b, 404c, 404d of one layer (e.g. first layer) are obscured by the corresponding rotary blades 406a, 406b, 406c, 406d of the other layer (e.g. second layer), and vice versa, in defining the aperture 408.

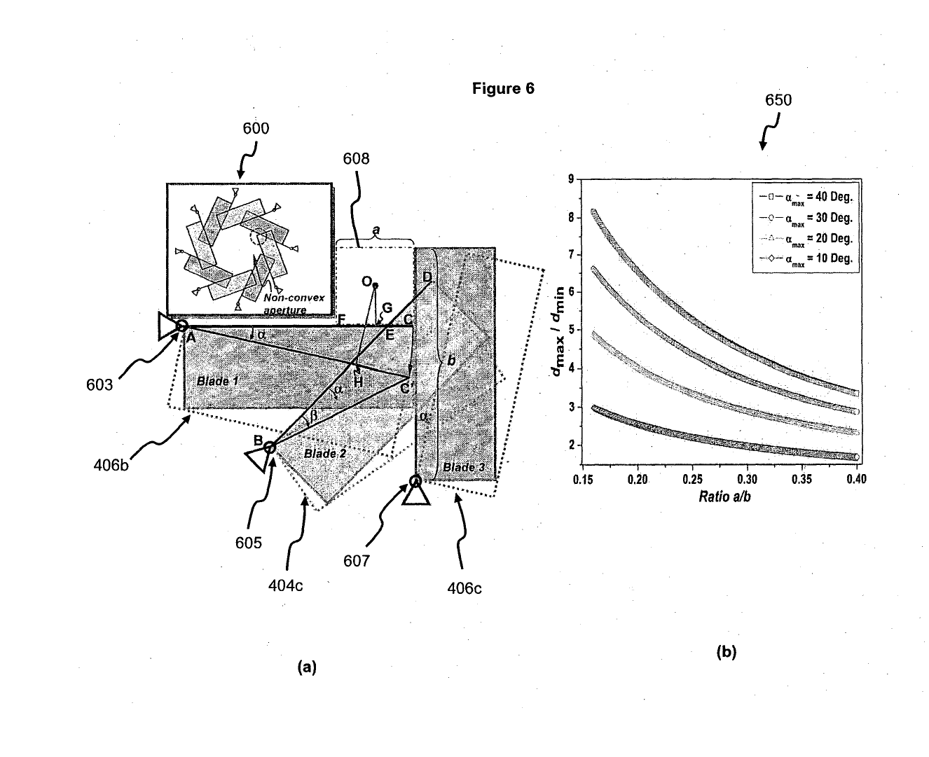

Additionally, unlike conventional iris diaphragms with apertures that are always configured as a convex regular polygon, the proposed MEMS iris diaphragm 400, due to usage of two-layers of rotary blades 404a, 404b, 404c, 404d, 406a, 406b, 406c, 406d, can also form a non-convex polygonal aperture when the blade rotation angles 504 are sufficiently large (i.e. see inset of FIG. 6a labelled as reference numeral 600). It is to be appreciated that while non-convex polygonal apertures in combination with suitable image processing algorithms may also provide satisfactory imaging results, however for the purpose of this (and subsequent) embodiment, the discussion herein will instead focus on convex polygonal aperture shapes. For the proposed MEMS iris diaphragm 400, non-convex polygonal apertures can be avoided with proper designing from the outset using an analytical method. It is to be appreciated that the subsequent discussion of the analytical method will be with reference to the MEMS iris, diaphragm 400 in FIG. 4, which adopts eight identical rotary blades 404a, 404b, 404c, 404d, 406a, 406b, 406c, 406d, with four rotary blades on each layer 404a, 404b, 404c, 404d, 406a, 406b, 406c, 406d. It is also to be further highlighted that the same analytical method can easily be extended to other designs with different numbers of rotary blades.

A first step of the analytical method is to consider a portion of the MEMS iris diaphragm 400, in which the portion includes any three selected adjacent rotary blades that are configured to obtain a smallest aperture. For sake of this discussion, those three selected rotary blades have reference numerals of 406b, 404c, 406c, in which the rotary blades with the reference numerals of 406b, 406c are from the second layer, and the rotary blade with the reference numeral of 404c is from the first layer. Additionally in this instance, for easy discussion of the analytical method, the three selected rotary blades 406b, 404c, 406c are further respectively labelled as “Blade 1” 406b, “Blade 2” 404c and “Blade 3” 406c. Also see FIG. 4a for the arrangement of the three selected rotary blades 406b, 404c, 406c with respect to the remaining rotary blades 404a, 404b, 404d, 406a, 406d of the proposed MEMS iris diaphragm 400. As illustrated in FIG. 6a, a square 608 (i.e. indicated by the dash-dotted lines) enclosed by the four rotary blades in the same (first/second) layer is assumed to have a length of “a” units, and accordingly a length “FC” is “a” units long. The length “FC” is defined to be a portion of the inner lengthwise edge of “Blade 1” 406b, as measured from the tip thereof. Further, the distance from the tip of each of “Blade 1” 406b, “Blade 2” 404c and “Blade 3” 406c to the corresponding pivoting points 603, 605, 607 (located at the opposing tips), that attaches to the MEMS rotary actuator 402, is assumed to have a length of “b” units. Hence, the length “AC”=“BD”=“b” units, in which “AC” and “BD” are respectively defined to be the inner lengthwise edges of “Blade 1” 406b, and “Blade 2” 404c. With reference to FIG. 6a, the length “AC” and “BD” of “Blade 1” 406b, and “Blade 2” 404c intersect at a point “E” to define respective sub-portions “AE” and “BE”. As a result of the symmetrical structure of the MEMS iris diaphragm 400, the sub-portions “AE” and “BE” can be expressed as equations (1) and (2):

AE=AC−EC=b−[a/(2+\sqrt{2})] (1)

BE=BD−ED=b−[(1+\sqrt{2})a/(2+\sqrt{2})] (2)

Next, the length “AB” is computed by applying the Law of Cosines on the triangle “ABE”, and is expressed as equation (3):

AB²=AE²+BE²−2(AE·BE)cos(π/4) (3)

Further, the diameter “d” of the proposed MEMS iris diaphragm 400 is defined as the diameter of the aperture 408, as formed. Accordingly, “dₘᵢₙ”=“2×OG”=“a” units, where “dₘᵢₙ” is the minimum aperture diameter, “O” is the centre point of the dash-dotted square 608, and “G” is a point on length “AC”, such that length “OG” is orthogonal to length “AC”. It is to be appreciated that the dash-dotted square 608 (which is formed at “dₘᵢₙ”) is considered as part of the aperture 408, after when the proposed MEMS iris diaphragm 400 is assembled.

When each of “Blade 1” 406b, “Blade 2” 404c and “Blade 3” 406c rotates clockwise about the respective pivoting points 603, 605, 607 through a blade rotation angle 504 of “α”, the aperture 408 of the MEMS iris diaphragm 400 enlarges due to the outward movement of “Blade 1” 406b, “Blade 2” 404c and “Blade 3” 406c away from the point “O”. The new positions of the “Blade 1” 406b, “Blade 2” 404c and “Blade 3” 406c after rotation are indicated by the dash-dotted rectangular boxes in FIG. 6a. In this case, with rotation of the “Blade 1” 406b, the inner lengthwise edge rotates and changes position from prior “AC” to “AC”, and the new diameter of the aperture 408 accordingly changes to “d=2×OH”, and “d” is expressed as equation (4):

$$d = 2 \sqrt{{( b - \frac{a}{2} )}^{2} + {( \frac{a}{2} )}^{2}} \{ sin [ tan ( \frac{a}{2 b - a} ) + α ] \} \qquad ( 4 )$$

where “H” is a point on length “AC′”, such that length “OH” is orthogonal to length “AC”.

As depicted in FIG. 6a, it is to be highlighted that if the angle ∠DBC′ (which is indicated as angle “β”) is greater than or equal to the angle “α”, the aperture 408 formed is a regular convex polygon; otherwise, the aperture 408 formed is a non-convex polygon. Subsequently, applying the Law of Sines on the triangle “ABC′”, and also in view of the following relationships where “∠AC′B=∠AEB+(α−β)=π/4+(α−β)” and “AC′=b”, equation (5) is derived:

sin(∠ABC′)=(b/AB)sin [π/4+(α−β)] (5)

Following from equation (5), it can be observed that that if the inequality (6), as expressed below, holds true:

(b/AB)≧\sqrt{2} (6)

the expression “sin [π/4+(α−β)]” defined in equation (5) must then be no greater than the value of “1/√2” in order to satisfy a requirement that the absolute value of “sin(∠ABC′)” must not be greater than one. In other words, the value of “β” must be greater than or equal to the value of “α” (i.e. “β≧α”), and consequently the aperture 408 formed will then always be a convex regular polygon, regardless of the blade rotation angle 504 of the rotary blades. Further, after combining equations (1), (2), and (3), it is determined that the inequality (6) is satisfied if the ratio “a/b” is greater than the value of “0.1591” (i.e. “a/b>0.1591”), and this ratio finding is thereafter utilised as an important design guideline for the proposed MEMS iris diaphragm 400 to avoid situations that might otherwise result in a non-convex aperture being formed for the MEMS iris diaphragm 400. For easy referral in the subsequent description hereinafter, the ratio “a/b” is termed as the design ratio.

To investigate the performance of the proposed MEMS iris diaphragm 400, results relating to an aperture adjustment ratio of the maximum aperture diameter “dₘₐₓ” to the minimum aperture diameter “dₘₐₓ” (i.e. “dₘₐₓ/dₘᵢₙ”) as a function of the design ratio “a/b” was calculated. Specifically, the design ratio “a/b” is defined to vary between the values of “0.16” to “0.4” for the purpose of this investigation. Further, the relationship between the aperture adjustment ratio “dₘₐₓ/dₘᵢₙ” and design ratio “a/b” was investigated for four different sets of “10°”, “20°”, maximum blade rotation angle “αₘₐₓ”, which are set at values of “10°”, “20°”, “30°” and “40°”. Values of the maximum aperture diameter “dₘₐₓ” are respectively obtained by replacing the variable “a” in equation (4) with corresponding values of “αₘₐₓ”, and the performance results depicting the relationship between the aperture adjustment ratio “dₘₐₓ/dₘᵢₙ” and design ratio “a/b” are shown in a graph 650 of FIG. 6b. It can clearly be observed from the graph 650 that the aperture adjustment ratio “dₘₐₓ/dₘᵢₙ” decreases non-linearly as the design ratio “a/b” increases. Accordingly, it will thus be appreciated that an optimal value of the design ratio “a/b” adopted for the proposed MEMS iris diaphragm 400 should approximately be “0.16”. As aforementioned, the above analytical analysis is similarly applicable for determining the optimal design ration “a/b” for other designs with different numbers of rotary blades.

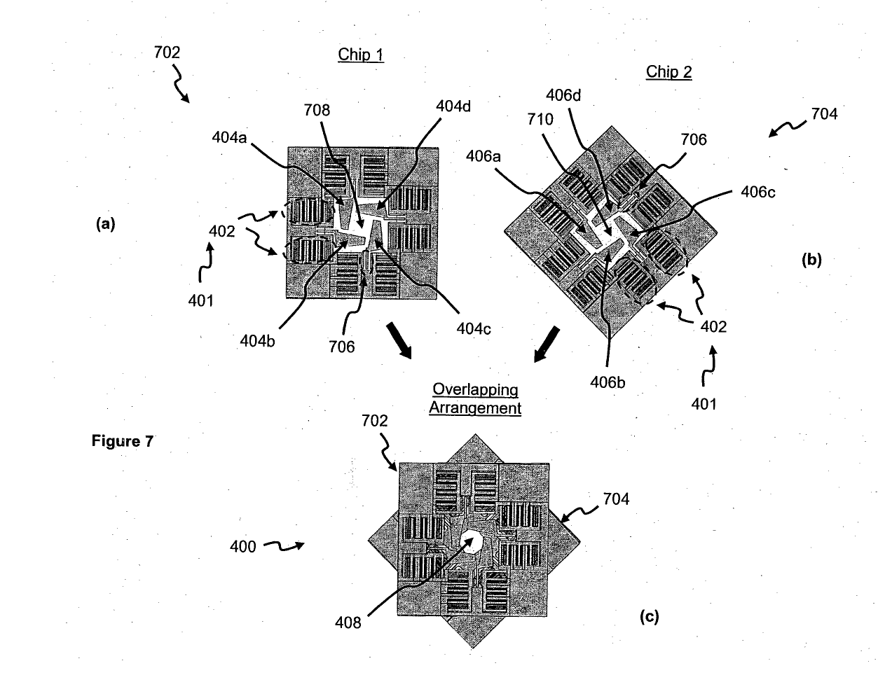

FIG. 7c shows an implementation of the proposed MEMS iris diaphragm 400, which is assembled from two MEMS chips, “Chip 1” 702 and “Chip 2” 704, shown in FIGS. 7a and 7b respectively. As afore described, the MEMS iris diaphragm 400 comprises first and second layers of rotary blades 404a, 404b, 404c, 404d, 406a, 406b, 406c, 406d, in which each corresponding layer is fabricated on “Chip 1” 702 and “Chip 2” 704 respectively. This is clearly depicted in FIGS. 7a and 7b, in which there are four configured rotary blades 404a, 404b, 404c, 404d, 406a, 406b, 406c, 406d in each of “Chip 1” 702 and “Chip 2” 704. Also in this implementation, the rotary blades 404a, 404b, 404c, 404d, 406a, 406b, 406c, 406d and associated MEMS rotary actuators 402 are developed on the same respective layers. Further, the rotary blades 404a, 404b, 404c, 404d, 406a, 406b, 406c, 406d of each layer are movably suspended via associated T-shaped flexural suspensions 706. It is to be appreciated that each T-shaped flexural suspension 706 can be designed in any shape as long as it can be configured to support rotating of the rotary blades 404a, 404b, 404c, 404d, 406a, 406b, 406c, 406d. In addition, each rotary blade 404a, 404b, 404c, 404d, 406a, 406b, 406c, 406d of each layer is arranged to be substantially parallel to opposing sides of corresponding “Chip 1” 702 and “Chip 2” 704, such that the four respective rotary blades 404a, 404b, 404c, 404d, 406a, 406b, 406c, 406d in result encircle a space located at the centre of corresponding “Chip 1” 702 and “Chip 2” 704 to, define respective square-like openings 708, 710.

To assemble the proposed MEMS iris diaphragm 400, “Chip 1” 702 is overlaid onto “Chip 2” 704 in a physical context, specifically by first aligning “Chip 1” 702 to “Chip 2” 704 as desired, and thereafter securely mounting “Chip 1” 702 to “Chip 2” 704 relative to each other, with a small vertical gap (as afore described) arranged between “Chip 1” 702 and “Chip 2” 704 in the mounted arrangement (to ensure that the rotary blades of each MEMS chip do not contact the rotary blades of the other MEMS chip), to form the proposed MEMS iris diaphragm 400. More specifically, to define the aperture 408, the second layer of rotary blades 406a, 406b, 406c, 406d are intentionally aligned and overlapped with a 45° rotation with respect to the first layer of rotary blades 404a, 404b, 404c, 404d, in which the 45° rotation is effected with reference along a light transmission direction (that is perpendicular to the plane of the paper). Also in this instance, “Chip 1” 702 is the top first layer, whereas “Chip 2” 704 is the bottom second layer in the assembled MEMS iris diaphragm 400. Moreover, the two layers are also arranged to be vertically separated via the small gap, as aforementioned, such that the rotary blades 404a, 404b, 404c, 404d of the first layer do not contact the rotary blades 406a, 406b, 406c, 406d of the second layer. In operation, when all the rotary blades 404a, 404b, 404c, 404d, 406a, 406b, 406c, 406d are simultaneously driven by the MEMS rotary actuators 402 to rotate clockwise, the aperture 408 thus enlarges progressively. In contrast, the aperture 408 progressively shrinks when the rotary blades 404a, 404b, 404c, 404d, 406a, 406b, 406c, 406d are driven to rotate counter-clockwise.

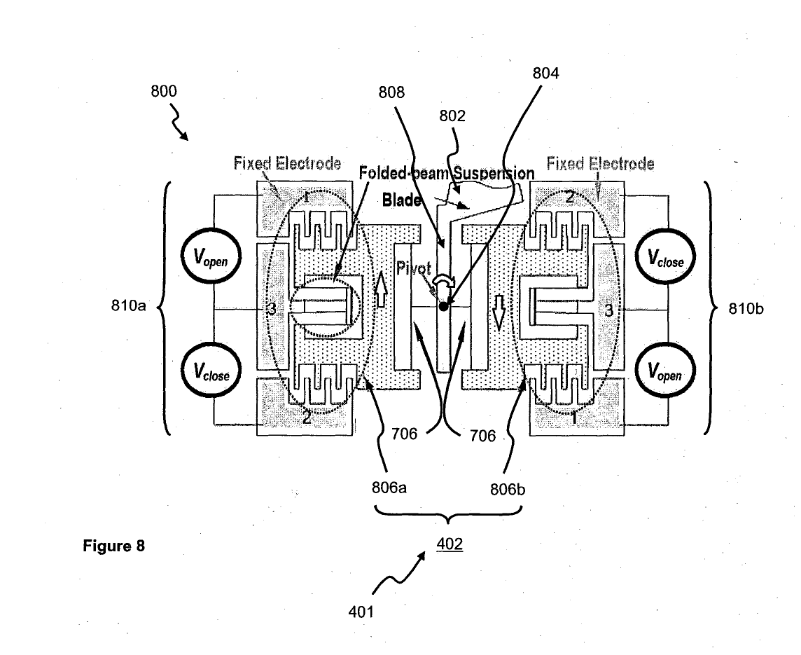

For Proof-of-Concept demonstration, a sample prototype device based on the implementation of FIG. 7c was fabricated and produced. The prototype device includes two MEMS chips fabricated using the Silicon-On-Insulator (SOI) Multi-User MEMS Processes (MUMPS) technique developed by MEMSCAP Incorporated of Durham, USA. Each fabricated MEMS chip is configured with four identical rotary blades, and for illustration, a schematic diagram 800 of one such rotary blade 802 is depicted in FIG. 8. As depicted, the rotary blade 802 is configured to rotate about a selected pivot point 804 driven by the associated MEMS rotary actuator 402 which is implemented as a pair of electrostatic comb-drive actuators 806a, 806b. In particular, the selected pivot point 804 is located on and along, the extension arm 808 of the rotary blade 802 and each electrostatic comb-drive actuator 802a, 802b is adjacently positioned on opposing sides of the extension arm 808. Again, it is to be highlighted that although the reference numerals used for the rotary blade 802 and extension arm 808 are different from those of equivalent elements in FIG. 4, it will be understood that this is to simplify discussion, and thus not to be construed that the rotary blade 802 and extension arm 808 of FIG. 8 are different (in basic structure or material composition) from the equivalent elements of FIG. 4.

Further, each comb-drive actuator 806a, 806b is configured with associated electrode circuitries 810a, 810b, in which each circuitry 810a, 810b comprises three fixed electrodes, respectively labelled with reference numerals “1”, “2” and “3” in FIG. 8. Moreover, it is to be highlighted that the arrangement of the two circuitries 810a, 810b are in reverse order with respect to each other (i.e. “1”, “3”, and “2” in contrast to “2”, “3” and “1”), as can clearly be seen from the plan view of FIG. 8. Each comb-drive actuator 806a, 806b is coupled to the rotary blade 802 via the associated T-shaped flexural suspension 706 that movably attaches to the extension arm 808. To enlarge the aperture 408, a first driving potential “Vₒₚₑₙ” is applied to the fixed electrodes “1” of both circuitries 810a, 810b, while keeping the corresponding fixed electrodes “2” and “3” grounded. This results in generation of electrostatic forces by the comb-drive actuators 806a, 806b to rotate the rotary blade 802 in a clockwise manner to consequently enlarge the aperture 408. Conversely, the aperture 408 can be shrunk by rotating the rotary blade 802 in a counter-clockwise manner, achieved by applying a second driving voltage “V_{close}” across the fixed electrodes “2” and “3” of both circuitries 810a, 810b and setting the first driving potential “Vₒₚₑₙ” (as applied across corresponding fixed electrodes “1”) to be at zero volts. It is to be appreciated that “V_{close}” and “Vₒₚₑₙ” are independent variables with respect to each other. It will be understood that while the above illustration for enlarging/shrinking the aperture 408 is provided only for one rotary blade 802 for ease of description, it needs to be applied similarly across all rotary blades of the prototype device in order to successfully effect the actual enlarging/shrinking of the aperture 408.

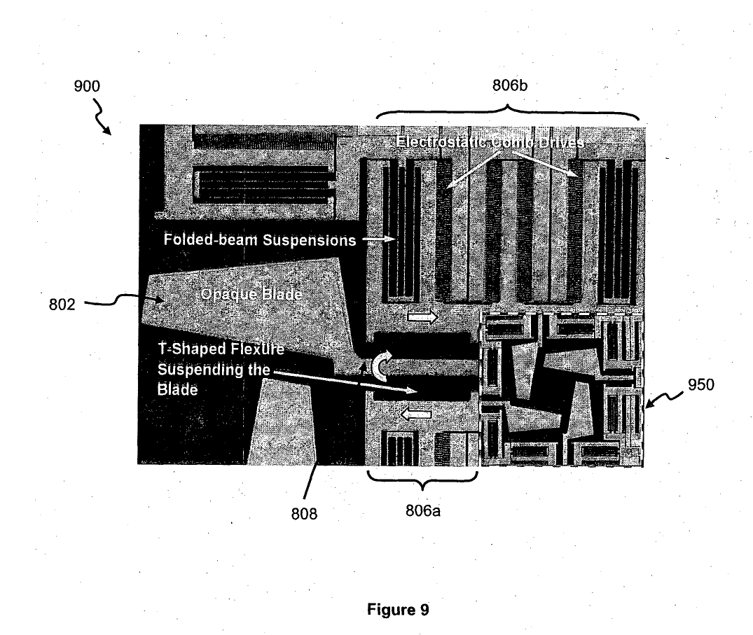

FIG. 9 shows an enlarged microscopic image 900 of a section of one fabricated MEMS chip, and the inset (labelled with reference numeral 950) shows the complete fabricated MEMS chip with four rotary blades. To assess the performance of the fabricated MEMS chip, the blade rotation angle 504 (of any one rotary blade) as a function of driving voltage was measured via an optical microscope. In this regard, the measurement indicates that each rotary blade of the MEMS chip is capable of clockwise rotation at an angle of 10° with the following configured parameters: “Vₒₚₑₙ”=100V and “V_{close}”=0V, and counter-clockwise rotation at an angle of 11° with the following configured parameters: “Vₒₚₑₙ”=0V and “V_{close}”=100V. It is also to be highlighted that each rotary blade being configured for clockwise rotation at an angle of 10° and counter-clockwise rotation at an angle of 11° is only an example for illustration in this instance, and other range of clockwise/counter-clockwise angles (e.g. greater than 10° and) 11° are also possible depending on a configuration required for an application of the proposed MEMS iris diaphragm 400. Additionally, the dynamic response characteristics of the rotary blades of the MEMS chip was assessed by actuating each rotary blade with a square wave-form driving voltage and cutting the rotary blade into a laser beam whose intensity is monitored with a high-speed photodetector. As assessed, the settling time of each rotary blade, within 5% of its steady state, is approximately less than 4 ms which indicates that the rotary blades are indeed capable of relatively fast tuning speed.

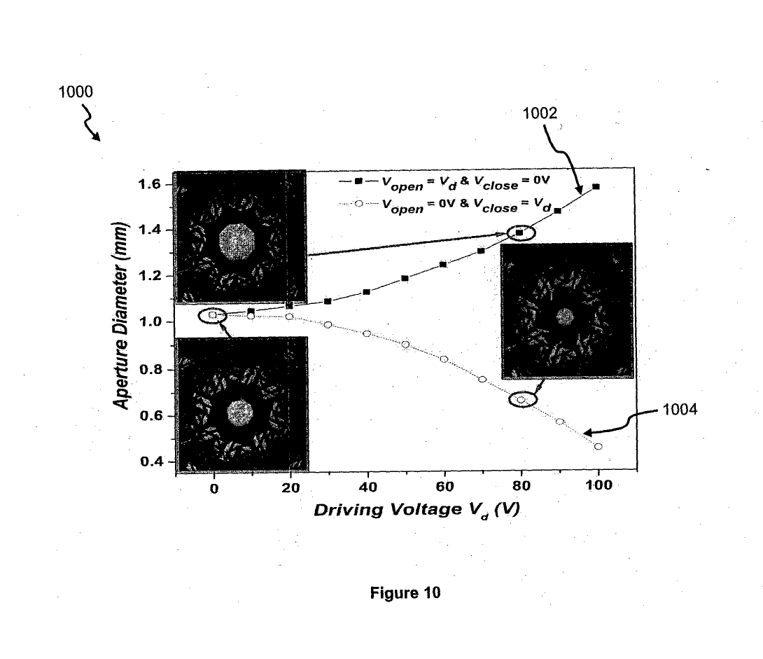

Thereafter, two identical MEMS chips, as fabricated, are arranged in an overlapping manner with respect to each other, as afore described with reference to FIGS. 7a to 7c, to produce the assembled prototype device. It is to be highlighted that the aperture 408 of the prototype device has a diameter of 1.03 mm in its original state, without any actuation being effected. The performance of the assembled prototype device was determined via a series of experimental assessments. Now with reference to the graph 1000 of FIG. 10, an upwardly curved line 1002 depicts the experimental results obtained when the first driving potential “Vₒₚₑₙ” is applied with a driving voltage (“V_{d}”) of between 0V to 100V, whilst the second driving potential “V_{close}” is maintained at 0V. Accordingly, it is determined that the diameter of the aperture 408 is adjustable to a maximum value of 1.56 mm from the original value of 1.03 mm. Similar measurements were also conducted with the first driving potential “Vₒₚₑₙ” is set to 0V and the second driving potential “V_{close}” allowed to vary at, the driving voltage “V_{d}” of between 0V to 100V. The corresponding experimental results obtained are depicted as a downwardly curved line 1004 in FIG. 10. It is to be noted that in this instance, the diameter of the aperture 408 shrinks to a minimum value of 0.45 mm. For illustration purposes, microscopic images showing the respective original, enlarged, and reduced diametric sizes of the aperture 408 in respect of the different driving potentials as applied, are also provided in FIG. 10. Indeed, the overall experimental results obtained are in good agreement with the analytical predictions as afore presented, and also is further to be highlighted that the prototype device is capable of providing more than three f-stops adjustable range, when used in a miniature camera lens system.

Accordingly, a method of adjusting a size of the aperture 408 of the proposed MEMS iris diaphragm 400 is disclosed as configuring the MEMS rotary actuators 402 to rotate the corresponding rotary blades 404a, 404b, 404c, 404d, 406a, 406b, 406c, 406d of the first and second layers in a non-contact manner, based on a desired blade rotation angle 504, in order to vary a size of the aperture 408 for allowing an appropriate amount of light therethrough, depending on an application intended for the proposed MEMS iris diaphragm 400.

Further embodiments of the invention will be described hereinafter. For the sake of brevity, description of like elements, functionalities and operations that are common between the embodiments are not repeated; reference will instead be made to similar parts of the relevant embodiment(s).

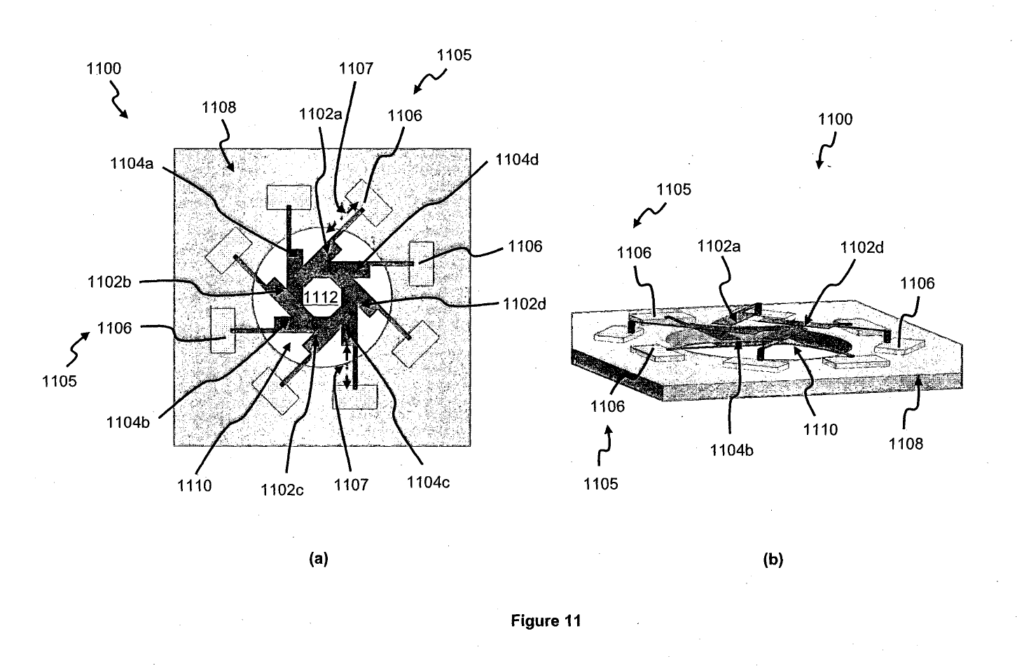

FIG. 11a shows another proposed MEMS iris diaphragm 1100 for an optical system according to a second embodiment, and FIG. 11b is an isometric view of FIG. 11a. Particularly, the proposed MEMS iris diaphragm 1100 is implemented based on a single MEMS chip. As shown in FIG. 11a, a first layer of rotary blades 1102a, 1102b, 1102c, 1102d and a second layer of rotary blades 1104a, 1104b, 1104c, 1104d are attached to corresponding rotary actuating devices 1105, each of which includes associated MEMS rotary actuators 1106, which are accordingly arranged on a MEMS substrate 1108 formed with a through-substrate hole 1110 in the centre. It is to be appreciated that the MEMS rotary actuators 1106 in this embodiment are similar to those MEMS rotary, actuators 402 of the first embodiment. Similar to the first embodiment, each rotary blade 1102a, 1102b, 1102c, 1102d, 1104a, 1104b, 1104c, 1104d has an integrally formed extension arm 1107 that extends from a lengthwise edge of the corresponding rotary blade 1102a, 1102b, 1102c, 1102d, 1104a, 1104b, 1104c, 1104d.

Further, the first and second layers form the top and bottom layers respectively. All the rotary blades 1102a, 1102b, 1102c, 1102d, 1104a, 1104b, 1104c, 1104d are specifically arranged to be suspended over the through-substrate hole 1110. The rotary blades 1102a, 1102b, 1102c, 1102d of the first layer, and the rotary blades 1104a, 1104b, 1104c, 1104d of the second layer, are attached to the associated MEMS rotary actuators 1106 through their extension arms 1107. The foregoing described can be more clearly understood by referring to FIG. 11b which shows the isometric illustration of the MEMS iris diaphragm 1100 of the second embodiment. Each rotary blade 1102a, 1102b, 1102c, 1102d, 1104a, 1104b, 1104c, 1104d is then adapted to be driven independently by the corresponding MEMS rotary actuators 1106.

In the suspended arrangement, the first layer of rotary blades 1102a, 1102b, 1102c, 1102d are further arranged to overlap the second layer of rotary blades 1104a, 1104b, 1104c, 1104d, and angularly spaced from one another to collectively define an aperture 1112 (which is polygonal-shaped) that is encircled by all the rotary blades 1102a, 1102b, 1102c, 1102d, 1104a, 1104b, 1104c, 1104d. The aperture 1112, being polygonal-shaped, is also in the form of an octagon for this embodiment. In operation, when the rotary blades 1102a, 1102b, 1102c, 1102d, 1104a, 1104b, 1104c, 1104d are driven to rotate in a clockwise manner, the aperture 1112 enlarges; conversely, the aperture 1112 shrinks when counter-clockwise rotation of the rotary blades 1102a, 1102b, 1102c, 1102d, 1104a, 1104b, 1104c, 1104d are effected. It is to be appreciated that the proposed MEMS iris diaphragm 1100 of this embodiment can be easily implemented using silicon micromachining technology. For example, the multi-layered MEMS rotary actuators 1106 and rotary blades 1102a, 1102b, 1102c, 1102d, 1104a, 1104b, 1104c, 1104d can be fabricated using surface micromachining, whereas the through-substrate hole 1110 can be fabricated using Deep Reactive Ion Etching (DRIE) of silicon technique.

According to a third embodiment, there is disclosed an optical system (not shown) that incorporates the MEMS iris diaphragm 400 of the first embodiment or the MEMS iris diaphragm 1100 of the second embodiment, depending on the suitability for an intended application, as will be understood by skilled persons.

In summary, the proposed MEMS iris diaphragm 400, 1100 is developed based on the design guidelines as afore described, and a prototype device was also implemented, using Silicon-On-Insulator (SOI) micromachining technology, for proof-of-concept demonstration. The proposed MEMS iris diaphragm 400, 1100 includes at least two layers of rotary blades 404a, 404b, 404c, 404d, 406a, 406b, 406c, 406d. Each rotary blade 404a, 404b, 404c, 404d, 406a, 406b, 406c, 406d is configured to be rotatably driven about a pivoting point by an associated MEMS rotary actuator 402. Additionally, the two layers of rotary blades 404a, 404b, 404c, 404d, 406a, 406b, 406c, 406d are formed in an overlapping arrangement relative to each other to define an aperture 408, 1112. Thereafter, controlled rotational motion of the rotary blades 404a, 404b, 404c, 404d, 406a, 406b, 406c, 406d, driven by MEMS rotary actuators 402, is used to increase or decrease the size of the aperture 408, 1112.

The rotary blades of the proposed MEMS iris diaphragm 400, 1100 are suspended with T-shaped flexural suspensions 706 and further, the rotary blades of the same layer or different layers do not slide between or contact one another during device operation. Therefore, this advantageously eliminates any possible generation of friction that may lead to unwanted wear and tear of the rotary blades, thus enabling the proposed MEMS iris diaphragm 400, 1100 to be suitably implemented using MEMS technology. Further, the proposed MEMS iris diaphragm 400, 1100 is non-fluid based, which means that complexities in device packaging and system integration are greatly reduced, and also allow for greater ease of actuation of the aperture 408, 1112, compared to conventional iris diaphragms. Additionally, the proposed MEMS iris diaphragm 400, 1100 has a large millimetre-scale aperture diameter adjustment range, compared to conventional devices that are instead arranged with in-plane translational moving micro-blades. Yet another advantage of the proposed MEMS iris diaphragm 400, 1100 is that it has a relatively fast response time of about a few milliseconds, in contrast to optofluidic-platform devices which have much slower response time of around a few hundred milliseconds.

Indeed, the proposed MEMS iris diaphragm 400, 1100 is non-fluid based, and is capable of providing a large adjustable aperture size range that is suitable for use in miniature imaging systems to control luminous flux, field of view and depth of field, as well as to prevent scattering of light and improve image quality. Possible applications of the proposed MEMS iris diaphragm 400, 1100 include adjustable apertures for miniaturised optics such as in smartphones, personal tablet PCs, endoscopic imaging systems, miniature surveillance cameras and the like.

The described embodiments should not however be construed as limitative. For example, any suitable MEMS rotary actuators 402, such as electro-thermal actuators (e.g. V-beam actuators, bimorph actuators, pseudo-bimorph actuators or the like), electrostatic actuators, electromagnetic actuators, and piezoelectric actuators, may be used to drive the rotary blades 404a, 404b, 404c, 404d, 406a, 406b, 406c, 406d for enlarging/shrinking the size of the aperture 408, 1112. It is also to be noted that various MEMS rotary actuators 402 and their variations are possible, as will be apparent to skilled persons. Further, arrangement of the MEMS rotary actuators 402 with respect to different layers of the rotary blades 404a, 404b, 404c, 404d, 406a, 406b, 406c, 406d may be varied. For example, the MEMS rotary actuators 402 may be developed on the same layer as the associated rotary blades 404a, 404b, 404c, 404d, 406a, 406b, 406c, 406d. Alternatively, the MEMS rotary actuators 402 may lie in a different separate layer with respect to the associated rotary blades 404a, 404b, 404c, 404d, 406a, 406b, 406c, 406d. Moreover, multiple configurations of the MEMS rotary actuators 402 and rotary blades 404a, 404b, 404c, 404d, 406a, 406b, 406c, 406d (i.e. not necessarily limited to only eight units) are also possible, which will be apparent to the skilled persons.

In the described embodiments, all the rotary blades 404a, 404b, 404c, 404d, 406a, 406b, 406c, 406d are rotated to maintain the polygonal shape of the aperture 408, 1112 but this may not be so. Indeed, the MEMS rotary actuators 402 may be arranged to rotate at least some of the rotary blades 404a, 404b, 404c, 404d, 406a, 406b, 406c, 406d while maintaining at least one of the rotary blades 404a, 404b, 404c, 404d, 406a, 406b, 406c, 406d stationary with respect to the others. In this instance, it would be appreciated that the size of the aperture 408, 1112 would still be adjusted although the shape of the aperture 408, 1112 may, however not be polygonal.

In addition, while the first and second embodiments describe the MEMS iris diaphragms 400, 1100 configured with eight rotary blades, it will also be understood that other designs with, different numbers of rotary blades are possible too. A device with three rotary blades in each layer to define a hexagonal-shaped aperture is one example. Further, although the rotary blades of the MEMS iris diaphragms 400, 1100 of the first and second embodiments are formed with straight edges, it will be appreciated by skilled persons that rotary blades with curved edges are possible as well, depending on requirements of different applications. In such an instance, the resulting aperture defined is correspondingly not polygonal in shape, but nonetheless may suitably be used as an aperture for optical systems that may have applications for such a non-polygonal-shaped aperture.

Referring again to the first and second embodiments, all the rotary blades of the MEMS iris diaphragms 400, 1100 may optionally be grouped together and configured to be driven by a common MEMS rotary actuator. Yet alternatively, the rotary blades may also be grouped into multiple independent groups, and all the associated rotary blades of each group is then attached to and be simultaneously driven by a common MEMS rotary actuator assigned to and configured for that particular group. It will be appreciated that the two above possible variations are alternatives to the configuration afore described in the first and second embodiments, in which each rotary blade is instead configured to be driven by its own associated MEMS rotary actuator.

Further, it is to be appreciated that the aperture 408, 1112 as formed can be of any polygon shape, including polygons with even number of edges (e.g. hexagon) or odd number of edges (e.g. pentagon), depending on the actual number of rotary blades configured for the MEMS iris diaphragms 400, 1100, which may vary based on needs of a particular relevant application. Following on then, it is also to be appreciated that, with reference to FIGS. 7a to 7c, the number of rotary blades of each MEMS chip, “Chip 1” 702 and “Chip 2” 704, may not necessarily be configured with the same number of rotary blades. For example, “Chip 1” 702 may be configured with an odd number of rotary blades while “Chip 2” 704 may be configured with an even number of rotary blades, in order to form an aperture that is a polygon with odd number of edges. Alternatively, to form an aperture of a polygon with even number of edges, both “Chip 1” 702 and “Chip 2” 704 may be configured with even number of rotary blades. Yet alternatively, to form an aperture of a polygon with even number of edges, both “Chip 1” 702 and “Chip 2” 704 may also be configured with odd number of rotary blades. Moreover, it is also to be appreciated that the aperture's size, according to different designs adopted, may preferably be variable between a maximum diameter of 5 mm (i.e. “dₘₐₓ”=5 mm) and a minimum diameter of 0 mm (i.e. “dₘᵢₙ”=0 mm).

Yet further, it is also to be highlighted that the extension arm 409, 1107 of each rotary blade may alternatively be omitted in certain suitable designs. In other words, each rotary blade is directly attached to the associated MEMS rotary actuator, without having to use the extension arm 409, 1107. Moreover, each rotary blade may be formed of any suitable shape, and not necessarily rectangular as described in the first embodiment, depending on the needs of the specific application for the MEMS iris diaphragms 400, 1100.

While the invention has been illustrated and described in detail in the drawings and foregoing description, such illustration and description are to be considered illustrative or exemplary, and not restrictive; the invention is not limited to the disclosed embodiments. Other variations to the disclosed embodiments can be understood and effected by those skilled in the art in practicing the claimed invention.

1. A miniaturized iris diaphragm for an optical system, comprising:
at least two layers of diaphragm structures with each layer having suspended blade members angularly spaced from each other, the at least two layers of blade members arranged to overlap and cooperate with each other to define an aperture to allow light to pass through; and
a rotary actuating device arranged to rotate at least some of the blade members of the at least two layers about their respective axis in a non-contact manner to vary the aperture's size.

2. A miniaturized iris diaphragm according to claim 1, wherein each blade member is suspended at one end to a at least one substrate.

3. A miniaturized iris diaphragm according to claim 1, wherein the blade members of each layer are suspended at one end to different substrates.

4. A miniaturized iris diaphragm according claim 2, wherein the rotary actuating device includes a plurality of rotary actuators, each actuator arranged to rotate one or more blade members.

5. A miniaturized iris diaphragm according to any of claim 1, wherein the rotary actuating device includes a single rotary actuator, which drives all blade members to rotate.

6. A miniaturized iris diaphragm according to claim 1, wherein each layer of the diaphragm structure has at least two blade members.

7. A miniaturized iris diaphragm according to claim 2, wherein the aperture has a polygonal shape.

8. A miniaturized iris diaphragm according to claim 7, wherein the polygonal shape is octagonal.

9. A miniaturized iris diaphragm according to claim 7, wherein the polygonal shape is hexagonal.

10. A miniaturized iris diaphragm according to claim 4, wherein each rotary actuator is an electrostatic comb-drive actuator.

11. A miniaturized iris diaphragm according to claim 1, wherein the rotary actuating device and the blade members are arranged on a common substrate.

12. A miniaturized iris diaphragm according to claim 2, wherein the rotary actuating device and the blade members are arranged on different respective substrates.

13. A miniaturized iris diaphragm according to claim 1, wherein each blade member is configured with substantially straight edges.

14. A miniaturized iris diaphragm according to claim 1, wherein each blade member is configured with curved edges.

15. A miniaturized iris diaphragm according to claim 1, wherein each blade member includes an extension arm for attaching to the rotary actuating device.

16. A miniaturized iris diaphragm according to claim 1, wherein each blade member is directly attached to the rotary actuating device.

17. A miniaturized iris diaphragm according to claim 1, wherein the at least two layers of diaphragm structures include first and second layers, the first layer having an odd number of blade members, and the second layer having an even number of blade members.

18. A miniaturized iris diaphragm according to claim 1, wherein the at least two layers of diaphragm structures include first and second layers, the first layer having an odd number of blade members, and the second layer having an odd number of blade members.

19. A miniaturized iris diaphragm according to claim 1, wherein the at least two layers of diaphragm structures include first and second layers, the first layer having an even number of blade members, and the second layer having an even number of blade members.

20. A miniaturized iris diaphragm according to claim 1, wherein the rotary actuating device is arranged to rotate each blade member of the at least two layers.

21. (canceled)

22. A method of adjusting a size of an aperture of a miniaturized iris diaphragm for an optical system, the miniaturized iris diaphragm including at least two layers of diaphragm structures with each layer having suspended blade members angularly spaced from each other, the at least two layers of blade members arranged to overlap and cooperate with each other to define an aperture to allow light to pass through, the method comprising:
rotating at least some of the blade members of the at least two layers about their respective axis in a non-contact manner, by a rotary actuating device, to vary the aperture's size.
